(19) United States
(12) Patent Application Publication
(10) Pub. No.: US 2025/0218831 A1
(43) Pub. Date: Jul. 3, 2025

(54) CONSTRUCTING A SUBSTRATE TOPOLOGY MAP BASED ON MEASURED PROPERTIES

(71) Applicant: APPLIED MATERIALS, INC., Santa Clara, CA (US)

(72) Inventors: Saitanay Naribole, Telangana (IN); Akash Goyal, Karnataka (IN); Helder Lee, San Jose, CA (US); Chandrakant Sapkale, Bangalore (IN); Hari Prasath Rajendran, Bangalore (IN); Vishwas Basavarajaiah Somashekar, Bangalore (IN)

(21) Appl. No.: 18/397,265

(22) Filed: Dec. 27, 2023

(51) Int. Cl. H01L 21/67; B25J 11/00; H01L 21/68; H01L 21/683; H01L 21/687

(52) U.S. Cl. CPC H01L 21/67288; H01L 21/68; H01L 21/6831; H01L 21/68707; B25J 11/0095

(57) ABSTRACT

A system includes a displacement sensor configured to measure one or more properties of a top surface of a substrate. The one or more properties are associated with at least one of substrate bow or substrate warpage. The system further includes a processing device communicatively coupled to the displacement sensor. The processing device is configured to receive, from the displacement sensor, sensor data indicative of the one or more properties of the top surface of the substrate, construct a substrate topology map based on the received sensor data, and cause management of the substrate based on the substrate topology map.

### TECHNICAL FIELD

Embodiments of the present disclosure generally relate to the construction of a substrate topology map, and more specifically relate to systems, methods and devices for determining substrate bow and/or substrate warpage based on measured properties of the surface of a substrate.

### BACKGROUND

Substrate processing can introduce warpage and/or bow to a substrate. The warpage and/or bow can adversely affect subsequent processing if not properly mitigated. Accurately determining the warpage and/or bow of a substrate can improve substrate processing and/or substrate handling.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Some of the embodiments described herein cover a system that includes a displacement sensor configured to measure one or more properties of a top surface of a substrate. The one or more properties are associated with substrate bow and/or substrate warpage. The system further includes a processing device communicatively coupled to the displacement sensor. The processing device is configured to receiver, from the displacement sensor, sensor data indicative of the one or more properties of the top surface of the substrate. The processing device is further configured to construct a substrate topology map based on the received sensor data. The substrate topology map is indicative of the substrate bow and/or the substrate warpage. The processing device is further configured cause management of the substrate based on the substrate topology map.

Additional or related embodiments described herein cover a method that includes receiving, from a displacement sensor, sensor data indicative of one or more properties of a top surface of a substrate. The one or more properties are associated with substrate bow and/or substrate warpage. The method further includes constructing a substrate topology map based on the received sensor data. The substrate topology map is indicative of the substrate bow and/or the substrate warpage. The method further includes causing management of the substrate based on the substrate topology map.

In further embodiments, a non-transitory machine-readable storage medium includes instructions that, when executed by a processing device, cause the processing device to perform operations including receiving, from a displacement sensor, sensor data indicative of one or more properties of a top surface of a substrate. The one or more properties are associated with substrate bow and/or substrate warpage. The operations further include constructing a substrate topology map based on the received sensor data. The substrate topology map is indicative of the substrate bow and/or the substrate warpage. The operations further include causing management of the substrate based on the substrate topology map.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a top schematic view of an example manufacturing system, according to aspects of the present disclosure.

FIG. 2 depicts a sectional view of a processing chamber, according to aspects of the present disclosure.

FIGS. 3A-3B illustrate simplified side views of systems for constructing a substrate topology map, according to aspects of the present disclosure.

FIGS. 4A-C illustrate simplified views of measured substrates, according to aspects of the present disclosure.

FIG. 5 is a flow chart of a method for determining substrate bow and/or substrate warp, according to aspects of the present disclosure.

FIG. 6A illustrates an example substrate topology map, according to aspects of the present disclosure.

FIG. 6B illustrates a simplified side view of a substrate, according to aspects of the present disclosure.

FIG. 7 is a flow chart of a method for managing a substrate based on a constructed substrate topology map, according to aspects of the present disclosure.

FIG. 8 depicts a diagrammatic representation of a machine in the example form of a computing device within which a set of instructions, for causing the machine to perform any one or more of the methodologies discussed herein, can be executed.

### DETAILED DESCRIPTION OF EMBODIMENTS

Embodiments of the present disclosure are directed to systems and methods for constructing a substrate topology map based on measured properties. During processing, one or more layers are often deposited onto a substrate. The deposited layers may have internal stresses that affect the substrate itself which can cause the substrate to bow and/or warp. Deposited layers with a greater thickness may contribute more to substrate bow and/or warpage than deposited layers with smaller thicknesses. However, where multiple layers are deposited on the substrate, the complexity of the bow and/or warpage of the substrate often increases. The issue of substrate bow and/or warp compounds with the addition of more layers, such as when manufacturing 3D NAND flash memory devices. Additionally, the high temperatures involved in some substrate processes can cause the substrate to warp.

Substrate bow and/or warpage adversely affects both processing and handling of the substrate. Warp or bow in the substrate leads to “high spots” on the substrate which lead to inconsistent processing across the surface of the substrate. Deposition or etch operations performed on a bowed or warped substrate may be non-uniform across the surface of the substrate, which can lead to a failure of the processed substrate to meet specification and subsequent scrapping of the substrate. Additionally, warp or bow in the substrate can affect the grip of a substrate-handling robot on the substrate. Substrate-handling robot end-effectors are often designed and constructed to handle substrates that have less than a threshold amount of bow and/or warpage. When an end effector handles a substrate having more than the threshold amount of bow and/or warpage, there is a chance that the end-effector may break the substrate during handling. For instance, the bowed or warped substrate may pop out of the grip of the end-effector and may break.

Aspects and implementations of the instant disclosure address the above-described and other shortcomings of conventional systems by providing a system (e.g., a substrate bow and/or warpage measuring system) to measure properties of the surface(s) of the substrate and construct a substrate topology map based on the measured properties, in order to determine characteristics of substrate bow and/or warpage of the substrate so that the bow and/or warpage can be properly mitigated during processing and handling. In some embodiments, a system includes a displacement sensor configured to measure one or more properties of a surface of the substrate. The measured properties may be associated with substrate bow and/or substrate warpage. For example, the one or more properties may be a distance from locations on the surface to the sensor. The displacement sensor may be a laser sensor and may be positioned above a stage (e.g., an aligner stage, etc.) where a substrate may be placed. The displacement sensor may take multiple sensor readings to measure the substrate surface topology. In some embodiments, the displacement sensor measures properties of the top surface of the substrate. In some embodiments, a processing device communicatively coupled to the displacement sensor receives sensor data from the displacement sensor. The sensor data may be indicative of the properties of the surface measured by the displacement sensor.

In some embodiments, the processing device constructs a substrate surface topology map based on the received sensor data. The topology map may be generated using the measured properties (e.g., such as the measured distance of the surface points, etc.) of the substrate surface. The topology map may be indicative of the substrate bow and/or the substrate warpage. In some embodiments, the topology map is used to manage the substrate. For example, the topology map may be used to affect the handling and/or the processing of the substrate. In some embodiments, the processing device causes the substrate to be handled (e.g., by a substrate-handling robot, etc.) based on the topology map. For example, the processing device may be configured to cause an end effector of the substrate-handling robot to grip the substrate at one or more edge locations satisfying a bow criterion and/or a warpage criterion. The one or more edge locations may be determined from the topology map. For example, the edge locations satisfying the bow criterion and/or the warpage criterion may be identified on the topology map.

In some embodiments, the processing device causes the substrate to be chucked on a substrate support (e.g., an electrostatic chuck, etc.) based on the topology map. For example, the processing device may cause more than a threshold amount of voltage to be applied to one or more zones of the substrate support. The one or more zones may correspond to regions of the substrate that are bowed or warped (e.g., “high spots” of the substrate, etc.). Causing more than the threshold amount of voltage to be applied may cause the substrate to become substantially flattened on the surface of the substrate support so that processing can occur uniformly across the substrate surface.

Embodiments of the present disclosure provide advantages over conventional systems described above. Particularly, some embodiments described herein can measure the bow and/or warpage of substrates and can initiate procedures to mitigate the effects of the substrate bow or warp. The mitigating effects can lead to increased uniformity in substrate processing and less breakage during substrate handling. Such effects may lead to greater yield and increased manufacturing system throughput. Power consumption may also be optimized, reducing overall system operating costs and reducing the system carbon footprint. Moreover, the substrate topology maps constructed according to embodiments described herein can be used for a variety of other uses, such as optimization of substrate heating and process recipe design.

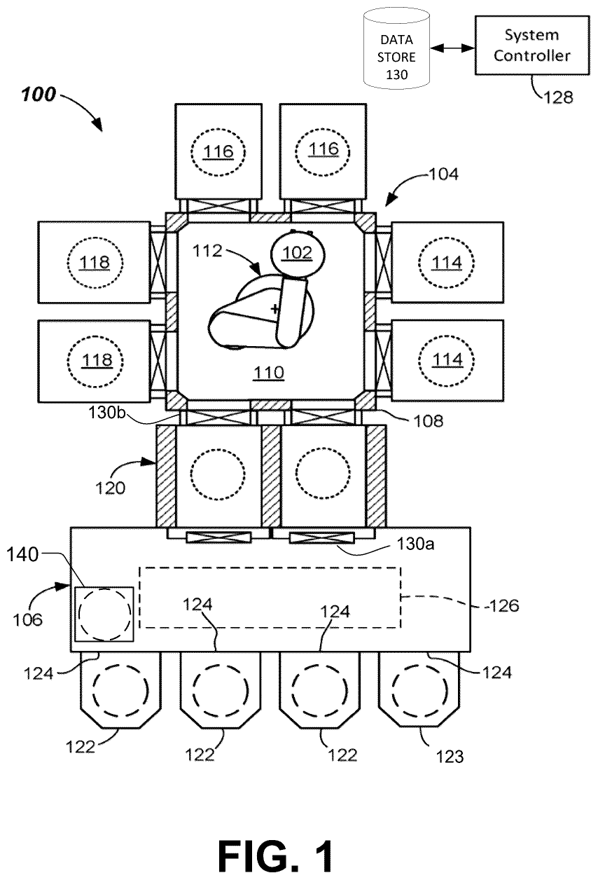

FIG. 1 is a top schematic view of an example manufacturing system 100, according to aspects of the present disclosure. Manufacturing system 100 can perform one or more processes on a substrate 102. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 100 can include a process tool 104 and a factory interface 106 coupled to process tool 104. Process tool 104 can include a housing 108 having a transfer chamber 110 therein. Transfer chamber 110 can include one or more process chambers (also referred to as processing chambers) 114, 116, 118 disposed therearound and coupled thereto. Process chambers 114, 116, 118 can be coupled to transfer chamber 110 through respective ports, such as slit valves or the like.

Process chambers 114, 116, 118 can be adapted to carry out any number of processes on substrates 102. A same or different substrate process can take place in each process chamber 114, 116, 118. A substrate process can include atomic layer deposition (ALD), physical vapor deposition (PVD), chemical vapor deposition (CVD), etching, annealing, curing, pre-cleaning, metal or metal oxide removal, or the like. In one example, a PVD process can be performed in one or both of process chambers 114, an etching process can be performed in one or both of process chambers 116, and an annealing process can be performed in one or both of process chambers 118. Other processes can be carried out on substrates 102 therein. Process chambers 114, 116, 118 can each include a substrate support assembly (e.g., an electrostatic chuck, etc.). The substrate support assembly can be configured to hold substrate 102 in place while a substrate process is performed.

In some embodiments, a process chamber 114, 116, 118 can include a carousel (also referred to as a susceptor). The carousel can be disposed in an interior volume of the process chamber 114, 116, 118 and can be configured to rotate about an axial center at the process chamber 114, 116, 118 during a process (e.g., a deposition process) to ensure process gases are evenly distributed. In some embodiments, the carousel can include one or more end effectors configured to handle one or more objects. For example, the end effectors can be configured to hold a substrate, a process kit, and/or a process kit carrier. One or more sensors can be disposed at the process chamber 114, 116, 118 and can be configured to detect a placement of an object on an end effector of the carousel, in accordance with embodiments described herein.

Transfer chamber 110 can also include a transfer chamber robot 112. Transfer chamber robot 112 can include one or multiple arms where each arm includes one or more end effectors at the end of each arm. The end effector can be configured to handle particular objects, such as substrates. Alternatively, or additionally, the end effector can be configured to handle process kits (i.e., using a process kit carrier). In some embodiments, transfer chamber robot 112 can be a selective compliance assembly robot arm (SCARA) robot, such as a 2 link SCARA robot, a 3 link SCARA robot, a 4 link SCARA robot, and so on.

A load lock 120 can also be coupled to housing 108 and transfer chamber 110. Load lock 120 can be configured to interface with, and be coupled to, transfer chamber 110 on one side and factory interface 106. Load lock 120 can have an environmentally-controlled atmosphere that can be changed from a vacuum environment (wherein substrates can be transferred to and from transfer chamber 110) to an at or near atmospheric-pressure inert-gas environment (wherein substrates can be transferred to and from factory interface 106) in some embodiments. In some embodiments, load lock 120 can be a stacked load lock having a pair of upper interior chambers and a pair of lower interior chambers that are located at different vertical levels (e.g., one above another). In some embodiments, the pair of upper interior chambers can be configured to receive processed substrates from transfer chamber 110 for removal from process tool 104, while the pair of lower interior chambers can be configured to receive substrates from factory interface 106 for processing in process tool 104. In some embodiments, load lock 120 can be configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate carriers 122 (e.g., Front Opening Unified Pods (FOUPs)) docked at various load ports 124 of factory interface 106. A factory interface robot 126 (shown dotted) can be configured to transfer substrates 102 between substrate carriers 122 (also referred to as containers) and load lock 120. In other and/or similar embodiments, factory interface 106 can be configured to receive replacement parts (e.g., process kits) from replacement parts storage containers 123. Factory interface robot 126 can include one or more robot arms and can be or include a SCARA robot. In some embodiments, factory interface robot 126 can have more links and/or more degrees of freedom than transfer chamber robot 112. Factory interface robot 126 can include an end effector on an end of each robot arm. The end effector can be configured to pick up and handle specific objects, such as substrates or process kits. Alternatively, or additionally, the end effector can be configured to handle objects such as process kits (e.g., using process kit carriers). In some embodiments, factory interface robot 126 may place substrates on and/or within a topology mapping tool 140 prior to and/or after transporting the substrates to load lock 120. The topology mapping tool 140 may be configured to measure one or more surface properties of a substrate for construction of a substrate topology map. The substrate topology map may be used to optimize substrate handling and/or substrate processing. Although the topology mapping tool 140 is illustrated as being disposed within factory interface 106, in some embodiments, the topology mapping tool 140 can be disposed in one or more of the substrate carriers 122.

Any conventional robot type can be used for factory interface robot 126. Transfers can be carried out in any order or direction. Factory interface 106 can be maintained in, e.g., a slightly positive-pressure non-reactive gas environment (using, e.g., nitrogen as the non-reactive gas) in some embodiments.

In some embodiments, transfer chamber 110, process chambers 114, 116, and 118, and load lock 120 can be maintained at a vacuum level. Manufacturing system 100 can include one or more vacuum ports that are coupled to one or more stations of manufacturing system 100. For example, first vacuum ports 130a can couple factory interface 106 to load locks 120. Second vacuum ports 130b can be coupled to load locks 120 and disposed between load locks 120 and transfer chamber 110.

Manufacturing system 100 can also include a system controller 128. System controller 128 can be and/or include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid state drives), a main memory, a static memory, a network interface, and/or other components. System controller 128 can execute instructions to perform any one or more of the methodologies and/or embodiments described herein. The instructions can be stored on a computer readable storage medium, which can include the main memory, static memory, secondary storage and/or processing device (during execution of the instructions).

In some embodiments, the system controller 128 can receive sensor data indicative of one or more surface properties of a substrate. The one or more properties may include surface topology data. In some embodiments, using the received sensor data, the system controller 128 constructs a substrate topology map that is indicative of the bow and/or warp of the substrate. In some embodiments, the system controller 128 causes the substrate to be managed (e.g., processed and/or handled, etc.) based on the substrate topology map as described herein.

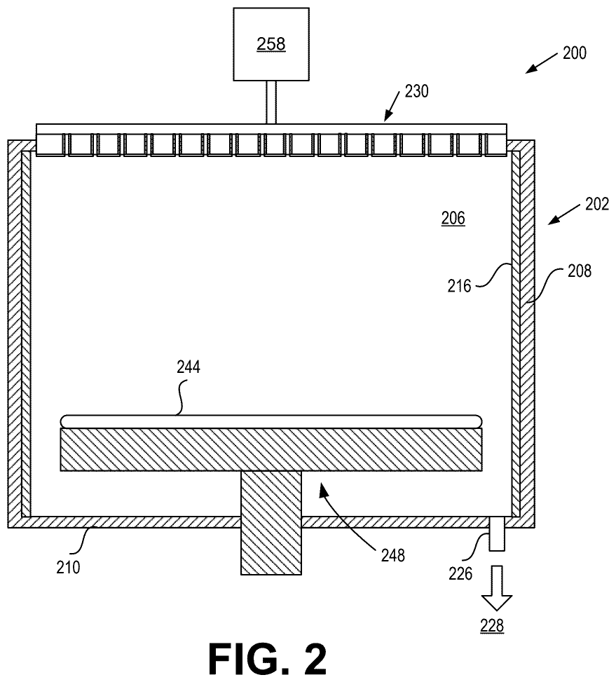

FIG. 2 is a sectional view of a processing chamber 200 (e.g., a semiconductor processing chamber, display processing chamber, etc.), in accordance with embodiments of the present disclosure. The processing chamber 200 may be used, for example, for processes in which a corrosive plasma environment having plasma processing conditions is provided. For example, the processing chamber 200 may be a chamber for a plasma etcher or plasma etch reactor, a plasma cleaner, and so forth. Other types of chambers may include deposition chambers, clean chambers, oxidation chambers, and so on. The processing chamber 200 may include a substrate support assembly 248, an electrostatic chuck (ESC), a ring (e.g., a process kit ring or single ring), a chamber wall, a base, a gas distribution plate, a showerhead 230, gas lines, a nozzle, a lid, a liner, a liner kit, a shield, a plasma screen, a flow equalizer, a cooling base, a chamber viewport, a chamber lid, and so on. The chamber components may be composed of metals, metal alloys, ceramics, and any combination thereof. The chamber components may include coatings, such as plasma resistant or corrosion resistant coatings. The coatings may be coatings deposited or grown via atomic layer deposition, plasma spray coating, chemical vapor deposition, ion-assisted deposition, sputtering, physical vapor deposition, electroplating, anodization, and so on.

In some embodiments, the processing chamber 200 includes a chamber body 202 and a showerhead 230 that enclose an interior volume 206. The showerhead 230 may include a showerhead base and a showerhead gas distribution plate. Alternatively, the showerhead 230 may be replaced by a lid and a nozzle in some embodiments. The chamber body 202 may be fabricated from aluminum, stainless steel or other suitable material. The chamber body 202 generally includes sidewalls 208 and a bottom 210. Any of the showerhead 230 (or lid and/or nozzle), sidewalls 208 and/or bottom 210 may include a coating.

An outer liner 216 may be disposed adjacent the sidewalls 208 to protect the chamber body 202. In some embodiments, the outer liner 216 is fabricated from aluminum oxide.

An exhaust port 226 may be defined in the chamber body 202, and may couple the interior volume 206 to a pump system 228. The pump system 228 may include one or more pumps and throttle valves utilized to evacuate and regulate the pressure of the interior volume 206 of the processing chamber 200.

The showerhead 230 may be supported on the sidewall 208 and/or top of the chamber body 202. The showerhead 230 (or lid) may be opened to allow access to the interior volume 206 of the processing chamber 200 in some embodiments, and may provide a seal for the processing chamber 200 while closed. A gas panel 258 may be coupled to the processing chamber 200 to provide process and/or cleaning gases to the interior volume 206 through the showerhead 230 or lid and nozzle. Showerhead 230 is used for processing chambers used for dielectric etch (etching of dielectric materials). The showerhead 230 may include a gas distribution plate (GDP) having multiple gas delivery holes 232 throughout the GDP. The showerhead 230 may include the GDP bonded to an aluminum showerhead base or an anodized aluminum showerhead base. The GDP 233 may be made from Si or SiC, or may be a ceramic such as Y₂O₃, Al₂O₃, YAG, and so forth. Showerhead 230 and delivery holes 232 may be characterized using system 100 or 150 in some embodiments. For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂. The lid, showerhead 230 (e.g., including showerhead base, GDP and/or gas delivery conduits/holes) and/or nozzle may be characterized using the system 100 according to an embodiment.

The substrate support assembly 248 may be disposed in the interior volume 206 of the processing chamber 200 below the showerhead 230 or lid. The substrate support assembly 248 may hold the substrate 244 during processing and may include an electrostatic chuck bonded to a cooling plate. In some embodiments, the electrostatic chuck includes multiple chucking zones that are individually controlled. In some embodiments, a controller (e.g., system controller 128 of FIG. 1) can cause more than a threshold amount of voltage to be applied to one or more of the chucking zones. The zones receiving more than the threshold amount of voltage may correspond to bowed and/or warped regions of the substrate. The increased amount of voltage applied to the chucking zones of the electrostatic chuck may cause the bowed or warped substrate to be substantially flattened on the substrate support assembly 248 for more uniform processing.

An inner liner may be on the periphery of the substrate support assembly 248. The inner liner may be a halogen-containing gas resist material such as those discussed with reference to the outer liner 216. In one embodiment, the inner liner 218 may be fabricated from the same materials of the outer liner 216. Additionally, the inner liner 218 may also be characterized using system 100 in some embodiments.

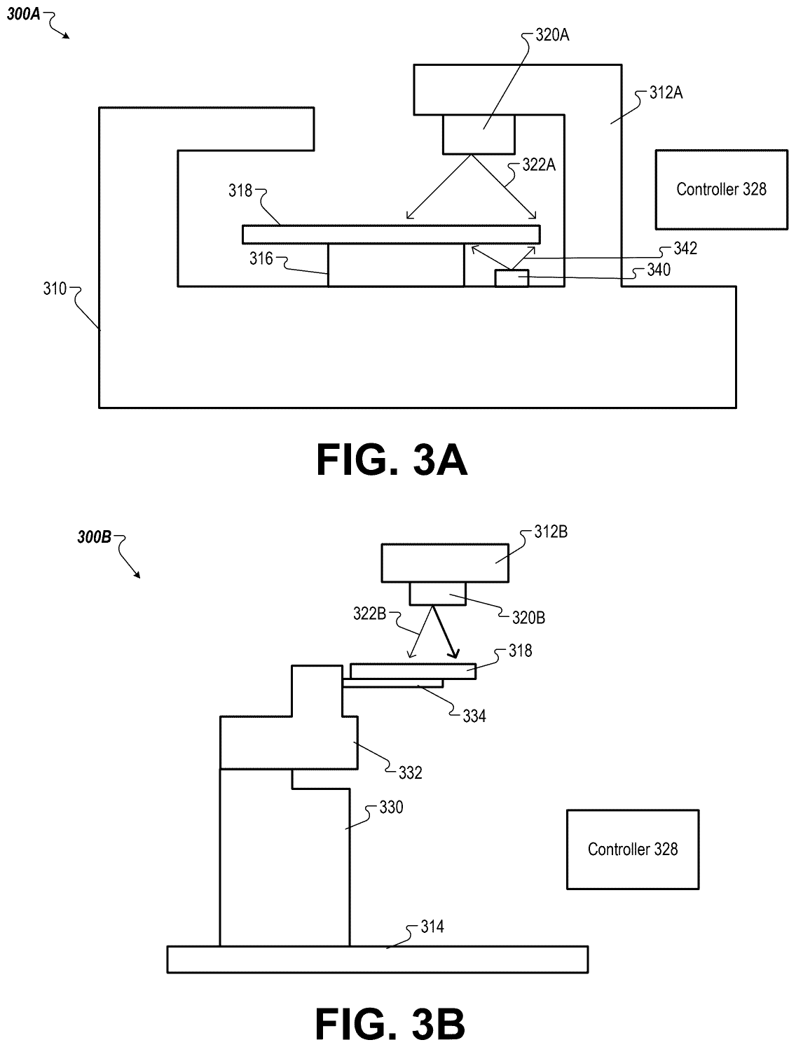

FIGS. 3A-3B illustrate simplified side views of systems for constructing a substrate topology map, according to aspects of the present disclosure. Referring to FIG. 3A, a system 300A is shown. In some embodiments, system 300A is disposed within a factory interface chamber of a substrate processing system. In some embodiments, system 300A includes a base 310. A sensor support 312A may be coupled to the base 310. In some embodiments, the sensor support 312A is integral to the base 310. A first displacement sensor 320A may be coupled to the sensor support 312A so that the top surface of a substrate 318 is within a field of view of the sensor. In some embodiments, first displacement sensor 320A is a laser sensor configured to measure the distance between the top surface of the substrate 318 and the sensor. The first displacement sensor 320A may be capable of measuring surface characteristics such as bow and/or warpage. In some embodiments, first displacement sensor 320A is a linear profile laser sensor. In other embodiments, first displacement sensor 320A is a point laser sensor. In some embodiments, first displacement sensor 320A is disposed between approximately 160 mm and approximately 460 mm from the top surface of the substrate 318. In some embodiments, the first displacement sensor 320A is disposed at a distance from the top surface of the substrate 318 suitable for the type and/or configuration of the sensor.

In some embodiments, the first displacement sensor 320A emits a beam 322A (e.g., a laser beam). In some embodiments, the first displacement sensor 320A is disposed above the substrate 318 and is configured to emit beam 322A downwards toward the top surface of substrate 318. The beam 322A may have a line profile or may have a point profile for scanning the top surface of the substrate 318. In some embodiments, the beam 322A has a line profile such that the first displacement sensor 320A can scan an entire radial surface profile of the top surface of substrate 318 (e.g., from the center of the substrate 318 to the edge of the substrate 318, etc.).

In some embodiments, the first displacement sensor 320A is coupled to a linear motion guide so that the sensor can move radially with respect to the substrate 318. For example, in embodiments where beam 322A has a point profile, the first displacement sensor 320A may move radially inward and/or radially outward with respect to the substrate 318 so that the sensor can measure the entire radial surface profile of the substrate 318. Individual point measurements may be stitched together (e.g., by controller 328) to create a measured surface profile.

In some embodiments, a second displacement sensor 340 emits a beam 342 to measure properties of the bottom surface of the substrate 318. In some embodiments, the beam 342 has a line profile or a point profile similar to beam 322A. In some embodiments, the second displacement sensor 340 is disposed beneath the substrate 318 and is configured to emit beam 342 upwards toward the bottom surface of substrate 318. The second displacement sensor 340 may measure the distance between the bottom surface of substrate 318 and the sensor. The second displacement sensor 340 may be capable of measuring surface characteristics such as bow and/or warpage.

In some embodiments, the substrate 318 is disposed on a carousel 316 while the first displacement sensor 320A and the second displacement sensor 340 measure properties of the top and bottom surface of the substrate 318. In some embodiments, the carousel 316 is an aligner to rotate (e.g., align) the substrate 318 according to instructions from the controller 328 (e.g., system controller 128 of FIG. 1). In some embodiments, the carousel 316 includes a vacuum chuck to secure the substrate 318. In some embodiments, the carousel 316 relies on friction to secure the substrate 318. In some embodiments, the carousel 316 rotates the substrate 318 so that the sensors 320A and 340 can measure the entire respect surface of substrate 318. For example, after the first displacement sensor 320A measures a first radial top surface profile, the carousel 316 rotates the substrate 318 a predetermined angle. The first displacement sensor 320A then measures a second radial top surface profile, subsequent to which the carousel 316 again rotates the substrate 318 so that the first displacement sensor 320A can measure another radial top surface profile. This measurement and rotation scheme continues until the substrate 318 has been rotated and measured about 360 degrees.

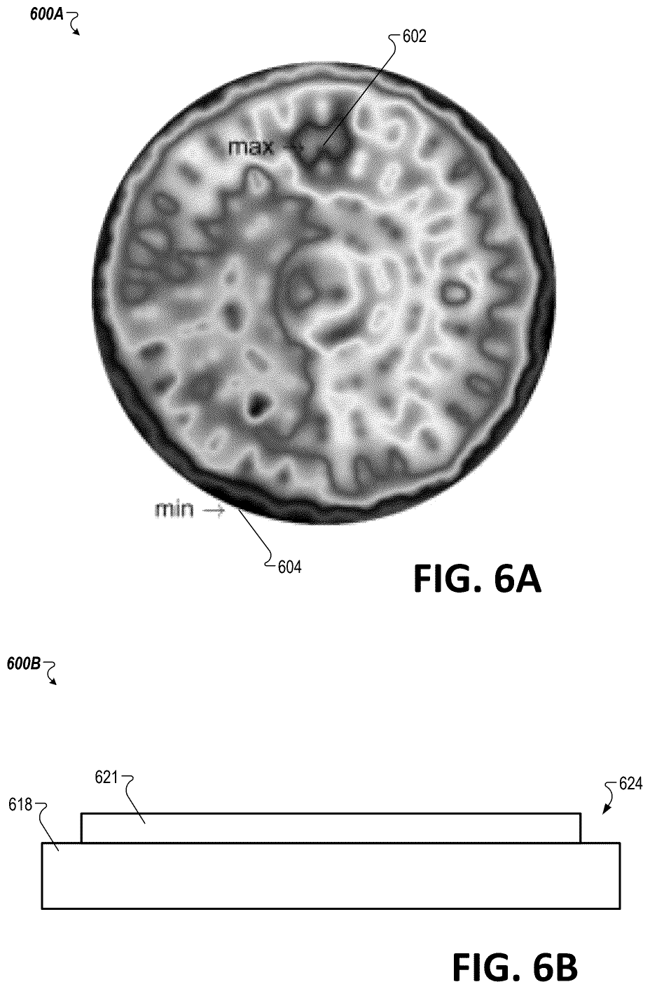

In some embodiments, the controller 328 receives sensor data from the first displacement sensor 320A and/or the second displacement sensor 340. The controller 328 may use the sensor data to construct a topology map of the substrate 318 and/or to determine a thickness of the substrate 318. In some embodiments, the topology map is indicative of surface characteristics and/or features of the substrate 318, such as bow or warp. Referring to FIG. 6A, an example substrate topology map 600A is illustrated, according to aspects of the present disclosure. In some embodiments, the topology map 600A indicates elevation features of the surface of a substrate. The elevation features may include one or more high spots 602 and/or one or more low spots 604. In some embodiments, the topology map 600A can be used to alter chucking voltages of a multi-zone electrostatic chuck. In some embodiments, the topology map 600A can be used to alter heating temperatures of a substrate support heater. In some embodiments, the topology map 600A can be used to alter pressures applied to a substrate in a chemical machining (e.g., chemical mechanical planarization, etc.) process. In some embodiments, the topology map 600A can be used to instruct a substrate-handling robot the edge locations on the substrate to grip. In some embodiments, the substrate topology map 600A is constructed based on sensor data received from the first displacement sensor 320A (e.g., a top surface displacement sensor, etc.) and/or the second displacement sensor 340 (e.g., a bottom surface displacement sensor, etc.). The sensor data may indicate the bow and/or warpage of the substrate. For example, sensor data indicating that the distance between the first displacement sensor 320A and a first location on the top surface of the substrate is less than the distance between the first displacement sensor 320A and a second location on the top surface of the substrate may indicate that the first location is higher than the second location. The differences in height between the first location and the second location indicate that the substrate is bowed and/or warped. The topology map 600A may indicate the differences in height between locations on the surface of the substrate and may therefore show bow and/or warpage of the substrate along with corresponding locations and/or regions of the bow and/ow warpage.

In some embodiments, an edge exclusion zone of a substrate can be determined based on the substrate topology map. Referring to FIG. 6B, a simplified side view 600B of a substrate 618 is illustrated, according to aspects of the present disclosure. In some embodiments, an edge exclusion zone 624 corresponds to an area on the surface of the substrate 618 at or near the edge where there is no deposited layer 621. For example, deposited layer 621 does not extend all the way to the edge of the surface of the substrate 618. The edge exclusion zone 624 corresponds to the region between the edge of the deposited layer 621 and the edge of the substrate 618. In some embodiments, the surface elevations indicated in the substrate topology map indicate the presence and/or size of the edge exclusion zone 624. In some embodiments, the substrate 618 can be handled based on the presence, size, and/or shape of the edge exclusion zone 624. For example, when the edge exclusion zone 624 is large, the substrate 618 can be gripped with a plunger (e.g., of a substrate handler, etc.) without damaging the deposited layer 621. When the edge exclusion zone 624 is small or nonexistent, the substrate 618 may not be gripped with a plunger. Instead, the substrate 618 may be handled slowly and carefully using the force of friction on the bottom surface to transport the substrate.

Referring to FIG. 3B, a system 300B is shown. In some embodiments, system 300B includes a substrate-handling robot 330 (e.g., a factory-interface robot, etc.) coupled to a base 314. The substrate-handling robot 330 includes one or more robot linkages 332. The one or more robot linkages 332 may include one or more arm linkages (e.g., upper arm, lower arm, forearm, writs, etc.). An end effector 334 is coupled to the one or more robot linkages 332. In some embodiments, the end effector 334 is configured to support and/or transfer the substrate 318. In some embodiments, the end effector 334 is to support the substrate 318 within a field of view of a displacement sensor 320B. In some embodiments, displacement sensor 320B emits a beam 322B (e.g., a laser beam, etc.) towards the top surface of substrate 318. In some embodiments, beam 322B is a point beam or a line beam, etc. as described above with respect to beam 322A. In some embodiments, displacement sensor 320B is coupled to a sensor support 312B. The sensor support 312B may be coupled to a sidewall of an enclosure (e.g., such as a factory interface chamber, etc.).

In some embodiments, the substrate 318 is supported by the end effector 334 while the displacement sensor 320B measures characteristics of the top surface of substrate 318. In some embodiments, the end effector 334 moves the substrate 318 so that the sensor 320B can measure substantially the entire top surface of the substrate 318. For example, the end effector 334 can move the substrate 318 side-to-side, the end effector 334 can move the substrate 318 radially, and/or the end effector 334 can rotate the substrate 318 about a central axis so that the sensor 320B can capture sensor data indicative of substantially the entire top surface of substrate 318. In some embodiments, displacement sensor 320B is coupled to a linear motion guide so that the sensor 320B can move relative to the substrate-handling robot 330. In some embodiments, the controller 328 receives sensor data from the displacement sensor 320B. The controller 328 may use the sensor data to construct a topology map corresponding to the measured features and/or measured characteristics of the substrate 318. In some embodiments, the topology map is indicative of bow and/or warpage of the substrate 318.

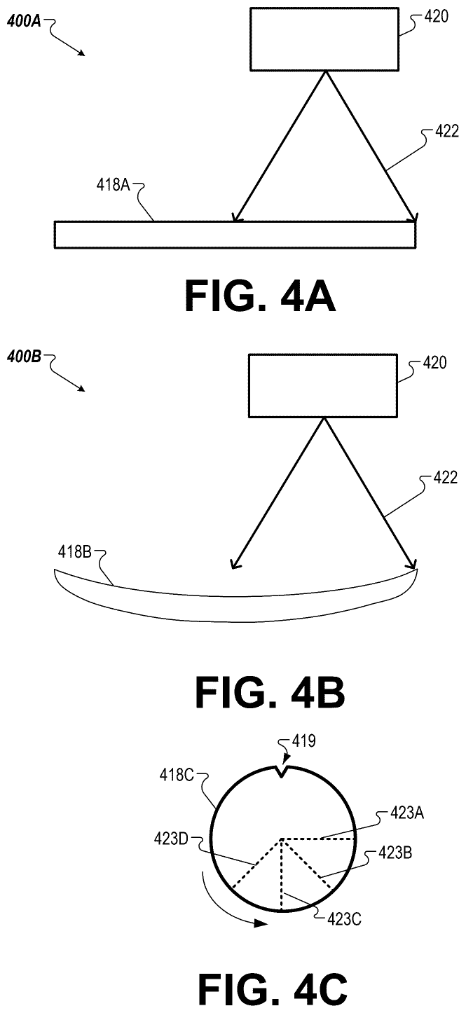

FIGS. 4A-C illustrate simplified views of measured substrates, according to aspects of the present disclosure. Referring to FIG. 4A, a simplified side view 400A depicting the measurement of a substrate 418A having substantially no bow or warp is illustrated. In some embodiments, the substrate 418A is a baseline substrate that is measured to generate baseline measurements. Subsequent measurements of other substrates (e.g., such as substrate 418B of FIG. 4B) may be compared to the baseline measurements generated with respect to substrate 418A. In some embodiments, the measured baseline substrate has a loading condition or boundary condition which may affect the substrate. For example, the substrate may flex due to gravity and the flexure may be measured.

In some embodiments, a displacement sensor 420 emits a beam 422 (e.g., a laser beam, etc.) towards the top surface of substrate 418A. The displacement sensor 420 may measure the distance between multiple locations on the top surface of the substrate 418A and the sensor itself. Sensor data indicative of the measurements may indicate that the measured substrate 418A has little to no bow or warpage. For example, the sensor data may indicate the substrate has less than 20 μm of warpage.

Referring to FIG. 4B, a simplified side view 400B depicting the measurement of a substrate 418B having bow is illustrated. The illustrated bow may be exaggerated for the sake of description. Sensor data generated by the displacement sensor 420 may be indicative of the elevation(s) of the top surface of the substrate 418B. The generated sensor data may indicate that the edge of the substrate 418B is closer to the sensor 420 than the middle of the substrate 418B. In some embodiments, the sensor data is conveyed to a processing device (e.g., a system controller such as controller 328 of FIGS. 3A-3B, system controller 128 of FIG. 1, etc.) for construction of a substrate topology map. In some embodiments, the processing device compares the measurements corresponding to substrate 418B with measurements corresponding to a measured baseline substrate (e.g., substrate 418A). The processing device may determine differences between the measurements of the baseline substrate 418A and the measurements of substrate 418B. The differences may correspond to a correction factor and may be used to determine the elevations of the surface of substrate 418B and to construct the substrate topology map. For example, sensor data corresponding to substrate 418B may be indicative of differences in measurement between substrate 418B and substrate 418A. The processing device determines the differences and subsequently determines the surface elevations of substrate 418B based on the differences. The processing device may use the surface elevations to construct a corresponding topology map of the substrate 418B. In the case of substrate 418B, the constructed topology map may indicate that the edge of the substrate 418B is higher than the middle of substrate 418B.

Referring to FIG. 4C, a simplified top view 400C depicting the measurement of a substrate 418C is illustrated. In some embodiments, the substrate 418C is disposed on a carousel (e.g., carousel 316 of FIG. 3A) while the surface of the substrate is measured. In some embodiments, multiple radial top surface profiles are measured at multiple angular positions. In some embodiments, a sensor measures a first radial top surface profile 423A at a first angular position of the substrate 418C. Upon completion of the measurement of the first radial top surface profile 423A, the substrate 418C may be caused to rotate a predetermined angle of rotation. A second radial top surface profile 423B at a second angular position may then be measured. The substrate 418C may then be caused to rotate the predetermined angle of rotation so that third radial top surface profile 423C and fourth radial top surface profile 423D, etc. are measured. In some embodiments, the predetermined angle of rotation is between approximately 1 degree and approximately 5 degrees, inclusive. In some embodiments, the multiple measured radial top surface profiles are used to construct a substrate topology map. In some embodiments, the substrate 418C is rotated and measured multiple times and the average of each of the measurements are used to construct the substrate topology map. The average of multiple measurements may be used to mitigate the effects of substrate vibration and/or sensor variability.

In some embodiments, sensor data may indicate the presence of a notch 419 in the edge of substrate 418C. The notch 419 may be an alignment notch to facilitate alignment of the substrate 418C for processing and/or handling. In some embodiments, the location of the notch 419 is determined based on the sensor data. In some embodiments, the substrate 418C is aligned (e.g., rotated) so that the notch 419 is in a target location for processing and/or handling. In some embodiments, the measurement of the multiple radial top surface profiles begins at the alignment notch 419. For example, the first angular position of the substrate 418C (e.g., for radial top surface profile measuring, etc.) may correspond to the location of the notch 419.

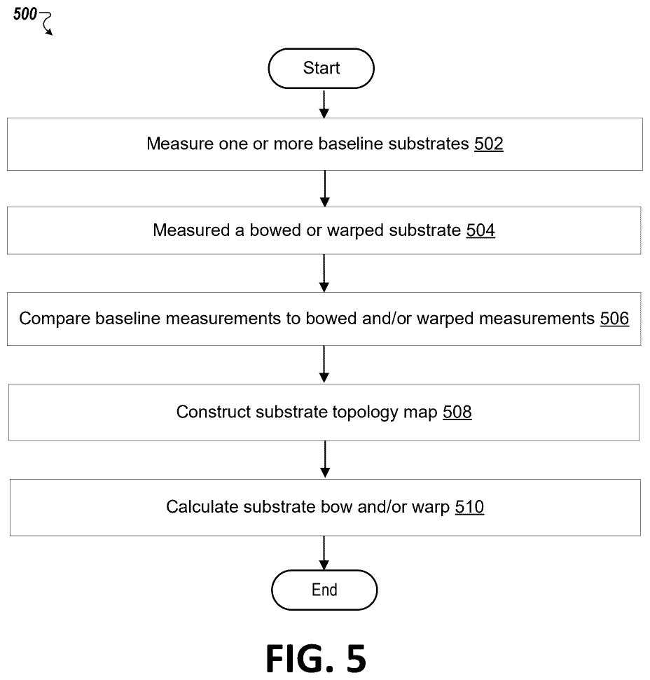

FIG. 5 is a flow chart of a method 500 for determining substrate bow and/or substrate warp, according to aspects of the present disclosure. Method 500 may be performed by a substrate topology mapping tool such as topology mapping tool 140 of FIG. 1 or one of systems 300A or 300B.

At block 502, one or more baseline substrates are measured (e.g., using one or more displacement sensors) to produce one or more baseline measurements. In some embodiments, the one or more baseline substrate have little-to-no bow or warp (e.g., less than approximately 20 μm of bow or warp, etc.). At block 504, bowed and/or warped substrates are measured. The bowed and/or warped substrates may be measured before processing and/or after processing (e.g., deposition processing, etch processing, etc.).

At block 506, measurements corresponding to the bowed and/or warped substrates are compared (e.g., by a processing device) with the baseline measurements. In some embodiments, differences between the measurements are determined to determine relative surface elevations of the bowed and/or warped substrates.

At block 508, a substrate topology map is constructed (e.g., by a processing device) representative of the relative surface elevations a measured bowed and/or warped substrate. In some embodiments, the substrate topology map is an elevation map of the measured bowed and/or warped substrate.

At block 510, substrate bow and/or warp is calculated (e.g., by a processing device) using the substrate topology map. In some embodiments, a processing device (e.g., of a controller, etc.) determines whether a measured substrate satisfies a substrate bow criterion or a substrate warpage criterion based on the calculated bow and/or calculated warp. In some embodiments, the substrate bow criterion corresponds to a maximum allowable threshold of substrate bow and the substrate warpage criterion corresponds to a maximum allowable threshold of substrate warpage.

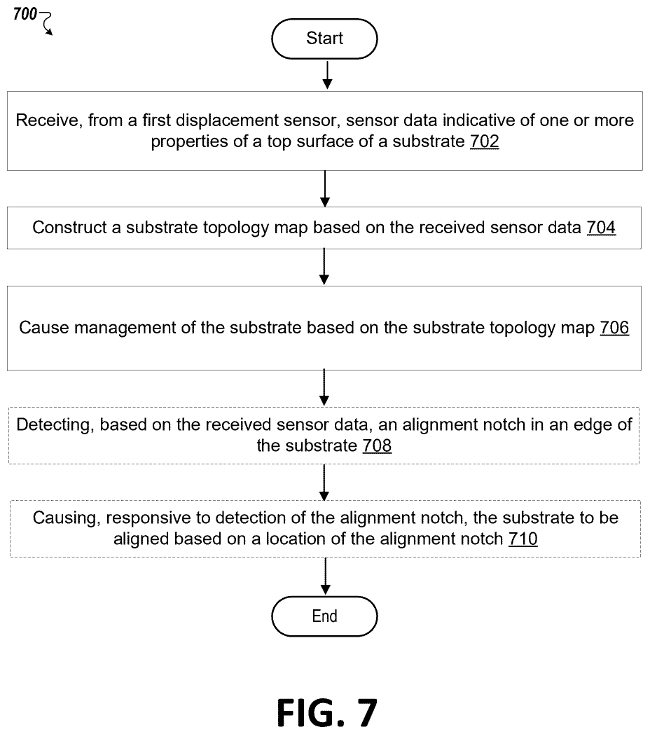

FIG. 7 is a flow chart of a method 700 for managing (e.g., handling and/or chucking) a substrate based on a constructed substrate topology map, according to aspects of the present disclosure. Method 700 is performed by processing logic that can include hardware (circuitry, dedicated logic, etc.), software (such as is run on a general purpose computer system or a dedicated machine), firmware, or some combination thereof. In one implementation, method 700 can be performed by a computer system, such as a computer system of a controller (e.g., system controller 128 of FIG. 1, controller 328 of FIGS. 3A-3B, etc.). In other or similar implementations, one or more operations of method 700 can be performed by one or more other machines not depicted in the figures.

At block 702, processing logic receives, from a first displacement sensor, sensor data indicative of one or more properties of a top surface of a substrate. The one or more properties may be associated with substrate bow and/or substrate warpage. In some embodiments, the first displacement sensor is a laser sensor that measures the distance between surface features and the sensor itself. In some embodiments, the sensor data is indicative of the relative surface elevations of the substrate. In some embodiments, processing logic receives, from a second displacement sensor, sensor data indicative of one or more properties of a bottom surface of the substrate.

At block 704, processing logic constructs a substrate topology map based on the received sensor data (e.g., received from the first displacement sensor and/or the second displacement sensor). The substrate topology map may be indicative of the substrate bow and/or the substrate warpage. In some embodiments, the relative surface elevations of the measured substrate are reflected in the substrate topology map.

At block 706, processing logic causes management of the substrate based on the substrate topology map. In some embodiments, causing management of the substrate includes (i) causing the substrate to be handled and/or (ii) causing the substrate to be chucked on a substrate support. The substrate may be caused to be handled and/or caused to be chucked based on the substrate topology map.

In some embodiments, processing logic uses the substrate topology map to identify one or more edge locations on the edge of the substrate satisfying a bow criterion and/or a warpage criterion. The bow criterion may correspond to less than a maximum allowable threshold of bow and the warpage criterion may correspond to less than a maximum allowable threshold of warpage. In some embodiments, the processing logic causes an end effector (e.g., of a substrate handling robot, etc.) to grip the substrate at the one or more identified edge locations.

In some embodiments, processing logic uses the substrate topology map to identify one or more bowed regions and/or warped regions of the measured substrate. The processing logic may identify one or more zones of a substrate support (e.g., an electrostatic chuck) that correspond to the identified bowed regions and/or warped regions. In some embodiments, when the substrate is placed on the substrate support, processing logic may cause voltage to be applied to the substrate support to electrically chuck the substrate to the support. In some embodiments, processing logic causes an increased amount of voltage to be applied to the identified zones. In some embodiments, the voltage applied to the identified zones is greater than the voltage applied to the other zones. In some embodiments, applying a greater amount of voltage to the identified zones causes the bowed or warped regions of the substrate to be more tightly chucked to the substrate support, causing the substrate to be sit substantially flat on the substrate support. This may cause the surface of the substrate to be more uniformly processed.

In some embodiments, processing logic identifies one or more heating zones of a substrate support that correspond to the identified bowed regions and/or warped regions. In some embodiments, processing logic causes the one or more heating zones to heat the substrate based on the substrate topology map. For example, the processing logic may cause the one or more identified heating zones to increase temperature or decrease temperature relative to the other heating zones.

In some embodiments, processing logic identifies one or more pressure zones (e.g., of a membrane, etc.) of a fixture for holding a substrate during a chemical machining (e.g., chemical mechanical planarization) process. The one or more identified pressure zones may correspond to the identified bowed regions and/or warped regions of the substrate. In some embodiments, when the substrate is held by the fixture, processing logic may cause increased or decreased pressure to be applied to the identified pressure zones so that the substrate is held substantially flat for the chemical machining process. This may cause the surface of the substrate to be more uniformly machined.

At optional block 708, processing logic detects, based on the sensor data received at block 702, an alignment notch in an edge of the substrate. In some embodiments, processing logic determines the location of the notch as indicated by the sensor data. At block 710, processing logic causes, responsive to detection of the alignment notch, the substrate to be aligned based on the location of the alignment notch. Processing logic may cause the substrate to be rotated (e.g., by an aligner, by a substrate-handling robot end-effector, etc.) to an orientation matching a target orientation for processing and/or handling.

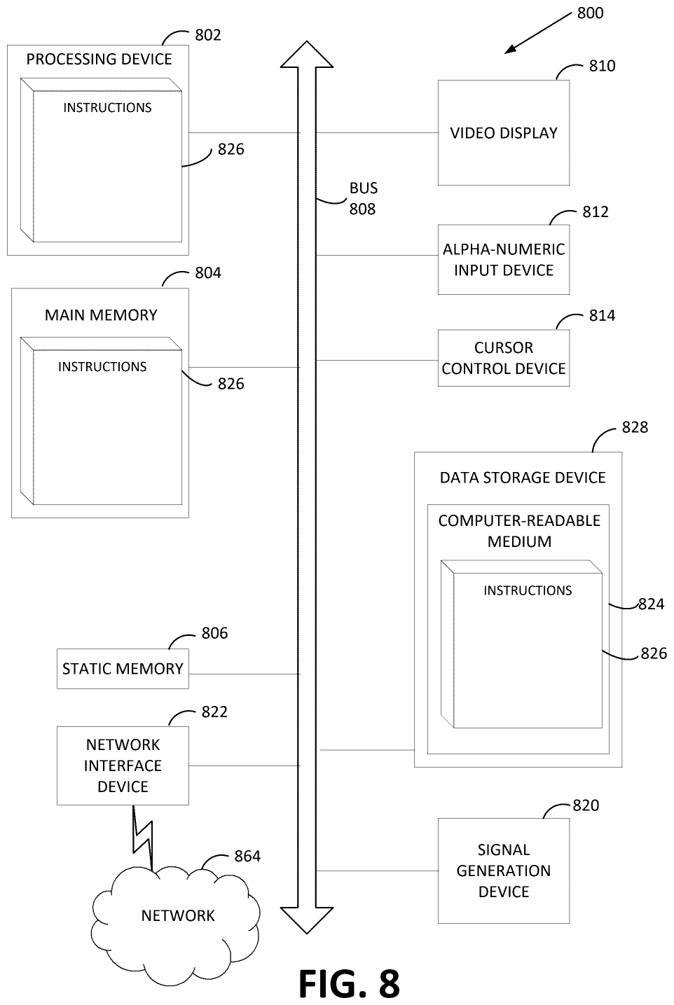

FIG. 8 depicts a diagrammatic representation of a machine in the example form of a computing device 800 within which a set of instructions, for causing the machine to perform any one or more of the methodologies discussed herein, can be executed. In alternative embodiments, the machine can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 800 can correspond to one or more of server machine 370, server machine 380, or predictive server 312 as described herein.

The example computing device 800 includes a processing device 802, a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 828), which communicate with each other via a bus 808.

Processing device 802 can represent one or more general-purpose processors such as a microprocessor, central processing unit, or the like. More particularly, the processing device 802 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. Processing device 802 can also be or include a system on a chip (SoC), programmable logic controller (PLC), or other type of processing device. Processing device 802 is configured to execute the processing logic for performing operations discussed herein.

The computing device 800 can further include a network interface device 822 for communicating with a network 864. The computing device 800 also can include a video display unit 810 (e.g., a liquid crystal display (LCD) or a cathode ray tube (CRT)), an alphanumeric input device 812 (e.g., a keyboard), a cursor control device 814 (e.g., a mouse), and a signal generation device 820 (e.g., a speaker).

The data storage device 828 can include a machine-readable storage medium (or more specifically a non-transitory machine-readable storage medium) 824 on which is stored one or more sets of instructions 826 embodying any one or more of the methodologies or functions described herein. A non-transitory storage medium refers to a storage medium other than a carrier wave. The instructions 826 can also reside, completely or at least partially, within the main memory 804 and/or within the processing device 802 during execution thereof by the computer device 800, the main memory 804 and the processing device 802 also constituting computer-readable storage media.

While the computer-readable storage medium 824 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system, comprising:
a first displacement sensor configured to measure one or more properties of a top surface of a substrate, wherein the one or more properties are associated with at least one of substrate bow or substrate warpage;
a processing device communicatively coupled to the first displacement sensor, wherein the processing device is configured to:
receive, from the first displacement sensor, sensor data indicative of the one or more properties of the top surface of the substrate;
construct a substrate topology map based on the received sensor data, wherein the substrate topology map is indicative of at least one of the substrate bow or the substrate warpage; and
cause management of the substrate based on the substrate topology map.

2. The system of claim 1, wherein causing management of the substrate based on the substrate topology map comprises causing the substrate to be chucked on a substrate support based on the substrate topology map, and wherein the processing device is further configured to cause a first zone of a plurality of zones of the substrate support to receive more than a threshold amount of voltage to electrically chuck the substrate to the substrate support, wherein, when the substrate is disposed on the substrate support, the first zone corresponds to a bowed region of the substrate or a warped region of the substrate reflected on the substrate topology map.

3. The system of claim 1, wherein causing management of the substrate based on the substrate topology map comprises causing the substrate to be handled based on the substrate topology map, and wherein the processing device is further configured to cause an end effector of a substrate handling robot to grip the substrate at one or more edge locations satisfying one or more of a bow criterion or a warpage criterion, wherein the one or more edge locations are indicated by the substrate topology map.

4. The system of claim 1, wherein the processing device is further configured to determine whether the substrate satisfies one or more of a substrate bow criterion or a substrate warpage criterion.

5. The system of claim 1, wherein the processing device is further configured to:
detect, based on the received sensor data, an alignment notch in an edge of the substrate; and
cause, responsive to detection of the alignment notch, the substrate to be aligned based on a location of the alignment notch.

6. The system of claim 1, wherein the first displacement sensor comprises at least one of a linear profile laser sensor or a point laser sensor, and wherein the first displacement sensor is configured to detect a distance between the top surface of the substrate and the first displacement sensor.

7. The system of claim 1, further comprising:
an aligner positioned within a factory interface chamber of a manufacturing system, wherein the first displacement sensor is configured to measure the one or more properties while the substrate is disposed on the aligner.

8. The system of claim 1, further comprising:
a substrate handling robot comprising an end effector, wherein the first displacement sensor is configured to measure the one or more properties while the substrate is supported by the end effector.

9. The system of claim 1, wherein the processing device is to cause the substrate to rotate relative to the first displacement sensor to multiple angular positions for measurement of multiple radial top surface profiles, each of the multiple radial top surface profiles corresponding to one of the multiple angular positions, and wherein the processing device is to construct the substrate topology map using the multiple measured radial top surface profiles.

10. The system of claim 1, further comprising:
a second displacement sensor configured to measure one or more properties of a bottom surface of the substrate, wherein the processing device is further configured construct the substrate topology map further based on sensor data received from the second displacement sensor.

11. The system of claim 1, wherein, to construct the substrate topology map, the processing device compares the received sensor data with baseline measurements corresponding to a measured baseline substrate.

12. The system of claim 1, wherein the processing device is further configured to:
determine, based on the substrate topology map, an edge exclusion zone; and
cause the substrate to be handled further based on the edge exclusion zone.

13. A method, comprising:
receiving, from a first displacement sensor, sensor data indicative of one or more properties of a top surface of a substrate, wherein the one or more properties are associated with at least one of substrate bow or substrate warpage;
constructing a substrate topology map based on the received sensor data, wherein the substrate topology map is indicative of at least one of the substrate bow or the substrate warpage; and
causing management of the substrate based on the substrate topology.

14. The method of claim 13, wherein causing management of the substrate based on the substrate topology map comprises causing the substrate to be chucked on a substrate support based on the substrate topology map, the method further comprising:
causing a first zone of a plurality of zones of the substrate support to receive more than a threshold amount of voltage to electrically chuck the substrate to the substrate support, wherein, when the substrate is disposed on the substrate support, the first zone corresponds to a bowed region of the substrate or a warped region of the substrate reflected on the substrate topology map.

15. The method of claim 13, wherein causing management of the substrate based on the substrate topology map comprises causing the substrate to be handled based on the substrate topology map, the method further comprising:
causing an end effector of a substrate handling robot to grip the substrate at one or more edge locations satisfying one or more of a bow criterion or a warpage criterion, wherein the one or more edge locations are indicated by the substrate topology map.

16. The method of claim 13, further comprising:
determining whether the substrate satisfies one or more of a substrate bow criterion or a substrate warpage criterion.

17. The method of claim 13, further comprising:
detecting, based on the received sensor data, an alignment notch in an edge of the substrate; and
causing, responsive to detection of the alignment notch, the substrate to be aligned based on a location of the alignment notch.

18. A non-transitory machine-readable storage medium comprising instructions that, when executed by a processing device, cause the processing device to perform operations comprising:
receiving, from a first displacement sensor, sensor data indicative of one or more properties of a top surface of a substrate, wherein the one or more properties are associated with at least one of substrate bow or substrate warpage;
constructing a substrate topology map based on the received sensor data, wherein the substrate topology map is indicative of at least one of the substrate bow or the substrate warpage; and
causing management of the substrate based on the substrate topology.

19. The non-transitory machine-readable storage medium of claim 18, wherein causing management of the substrate based on the substrate topology map comprises causing the substrate to be chucked on a substrate support based on the substrate topology map, and wherein the processing device is to perform operations further comprising:
causing a first zone of a plurality of zones of the substrate support to receive more than a threshold amount of voltage to electrically chuck the substrate to the substrate support, wherein, when the substrate is disposed on the substrate support, the first zone corresponds to a bowed region of the substrate or a warped region of the substrate reflected on the substrate topology map.

20. The non-transitory machine-readable storage medium of claim 18, wherein causing management of the substrate based on the substrate topology map comprises causing the substrate to be handled based on the substrate topology map, and wherein the processing device is to perform operations further comprising:
causing an end effector of a substrate handling robot to grip the substrate at one or more edge locations satisfying one or more of a bow criterion or a warpage criterion, wherein the one or more edge locations are indicated by the substrate topology map.
